(19) United States
(12) Patent Application Publication
(10) Pub. No.: US 2020/0012158 A1
(43) Pub. Date: Jan. 9, 2020

(54) LIGHT IRRADIATION DEVICE

(71) Applicant: V TECHNOLOGY CO., LTD., Kanagawa (JP)

(72) Inventor: Toshinari ARAI, Kanagawa (JP)

(21) Appl. No.: 16/572,213

(22) Filed: Sep. 16, 2019

Related U.S. Application Data
(63) Continuation of application No. PCT/JP2018/015062, filed on Apr. 10, 2018.

(30) Foreign Application Priority Data
Apr. 17, 2017 (JP) 2017-081272

(51) Int. Cl. G02F 1/1337; F21V 9/14; G03F 7/20; H01L 21/027; F21V 13/04; F21V 5/04

(52) U.S. Cl. CPC G02F 1/133788; G02F 1/133711; F21V 9/14; F21V 5/04; H01L 21/027; G03F 7/70058; F21V 13/04; G03F 7/20

(57) ABSTRACT

In a second direction (y direction) substantially orthogonal to a first direction (x direction), a distance between a light transmission region formed on a mask and an optical axis Ax is A times as long as a distance between an exposure pattern formed on a substrate W by light that passed through the light transmission region (A is a number that is equal to or greater than 1).

### CROSS-REFERENCE TO RELATED APPLICATIONS

This application is a continuation application of International Patent Application No. PCT/JP2018/015062 filed on Apr. 10, 2018, which claims priority to Japanese Patent Application No. 2017-081272 filed on Apr. 17, 2017, the entire contents of which are incorporated by reference.

### TECHNICAL FIELD

The present invention relates to a light irradiation device.

### BACKGROUND ART

Patent Document 1 discloses a light irradiation device in which light emitted from a lamp is focused by an elliptical focusing mirror, passes through an input lens, a polarizing element, an integrator lens, a collimator lens, and the like, and then is emitted onto a workpiece as parallel light emitted from the collimator lens via a mask to perform photoalignment for each divided pixel.

Patent Document 2 discloses an exposure device including: a light source that irradiates a workpiece with light; a polarization element that branches the light emitted onto the workpiece from the light source, based on a polarized component; a first uniformization unit that is provided between the light source and the polarization element and uniformizes an intensity distribution of light incident from the light source; a first collimating unit that is provided between the first uniformization unit and the polarization element and converts the light the intensity distribution of which has been uniformized by the first uniformization unit into parallel light; a second uniformization unit that is provided between the first collimating unit and the polarization unit, receives the light with the uniformized intensity distribution converted into parallel light by the first uniformization unit, and uniformizes intensities of a plurality of beams of light incident on incident points with respect to the polarization element such that the light is made incident on the incident points at a uniform angle; and a second collimating unit that is provided between the second uniformization unit and the polarization element and converts the light as a result of uniformizing the intensities of the plurality of beams of light by the second uniformization unit. A fly-eye lens is used for the first and second uniformization units, and a condenser lens is used for the first and second collimating units.

### CITATION LIST

### Patent Document

Patent Document 1: JP 11-194345 A
Patent Document 2: JP 2013-167832 A

In the light irradiation device described in Patent Document 1, the intensity distribution of light condensed by the elliptical condenser mirror is not uniform. Thus, light passing through the collimator lens cannot be parallel light in a strict sense, meaning that the workpiece is irradiated with light inclined relative to the optical axis. FIG. 17 is a diagram illustrating positional shift of an exposure pattern in a case where light inclined relative to the optical axis is emitted. Light L2 passing through an aperture 111a of a mask pattern of a photomask 111 while being inclined relative to the optical axis results in a position P2 of the exposure pattern where the workpiece W is exposed is shifted from a position of an originally intended position P1 (the position of the exposure pattern where the workpiece W is exposed by light L1 that passed through the aperture 111a while being in parallel with the optical axis). In particular, even a slight positional shift of the exposure pattern results in defects, in a case that photoalignment is performed for a substrate for a high-definition display.

In Patent Document 2, the workpiece is irradiated with parallel light the intensity distribution of which has been uniformized, using the first and the second uniformization units and the first and the second collimating units. Thus, the actual position of the exposure pattern where the exposure takes place can match the position where the exposure pattern is originally intended to be formed. However, the invention described in Patent Document 2 requires two uniformization units (fly-eye lenses) to be used, and thus results in an increase in the size and the manufacturing cost of the device.

One or more embodiments of the present invention is made in view of the above and seeks to provide a light irradiation device enabling a position of an exposure pattern that is actually exposed to be matched with a position where the exposure pattern is originally intended to be formed, using a single set of a uniformization unit and a collimating unit.

### SUMMARY OF INVENTION

A light irradiation device that forms an exposure pattern in a band-shape along a first direction of a substrate includes: a light source that emits light; a mask that is formed at a position where a light transmission region having a band-shape along the first direction does not intersect with an optical axis; a collimating unit (collimator) that converts the light emitted from the light source into parallel light to be emitted onto the mask; and a fly-eye lens that is disposed between the light source and the collimating unit and achieves a uniform distribution of an intensity of the light emitted onto the mask. A distance between the light transmission region and the optical axis in a second direction substantially orthogonal to the first direction is A times as long as a distance between an exposure pattern formed on the substrate by light that passed through the light transmission region and the optical axis, A being a number that is equal to or larger than 1.

With the light irradiation device of one or more embodiments of the present invention, in the second direction substantially orthogonal to the first direction along the band-like (band-shaped) exposure pattern, the distance between the light transmission region formed in the mask and the optical axis is A (A is a number that is equal to or larger than 1) times as long as the distance between the position of the exposure pattern formed on the substrate by light that passed through the light transmission region and the optical axis. This may match the position where the exposure pattern is originally intended to be formed and the position of the exposure pattern actually exposed. Also, using such a mask may be a set of fly-eyewear lenses and condenser lenses, which can prevent the device from becoming larger and lower manufacturing costs.

Here, the light irradiation device may further include: a stage on which the substrate is placed; and a mask movement unit that moves the mask along a direction substantially orthogonal to a top surface of the stage. As a result, even when the distance between the mask and the substrate is different, the position of the exposure pattern can be shifted by the shift amount with the same mask.

Here, the light source may include a lamp that emits light and a reflection mirror that is provided on a back side of the lamp, and the light irradiation device may further include a lamp movement unit that moves the lamp along the optical axis. This allows the position of the exposure pattern to be efficiently shifted.

According to one or more embodiments of the present invention, only a set of uniformization and collimating units (collimators) may match the position where the exposure pattern is originally intended to be formed and the position of the exposure pattern to be actually exposed.

### BRIEF DESCRIPTION OF DRAWINGS

FIG. 1 is a schematic perspective view of a polarized light irradiation device 1 according to a first embodiment.

FIG. 2 is a schematic front view illustrating the polarized light irradiation device 1 with a portion thereof enlarged.

FIG. 3 is a schematic view of a fly-eye 214 as viewed from a direction substantially orthogonal to an optical axis Ax.

FIG. 4 is a diagram illustrating a light transmission region formed in a mask 32, and is a schematic view of the mask 32 when viewed in plan view.

FIG. 5 is a block diagram illustrating an electrical configuration of the polarized light irradiation device 1.

FIG. 6 is a graph illustrating an intensity S1 of light incident on the fly-eye lens 214, and illustrates the relationship between a position on the yw plane of the fly-eye lens 214 and the intensity of the light.

FIG. 7 is a result of adding the light intensity S1 illustrated in FIG. 6 along a line extending in the direction w, for each position in the y direction of the fly-eye lens 214 (light intensity S2).

FIG. 8 is a comparison between the ideal incident light passing through the light transmission region 32a and the actual incident light shown in Table 1 in the case where the position of the workpiece W in Table 1 is 125.

FIG. 9 is a graph showing the relationship between the position in the y direction and the shift amount of the workpiece W.

FIG. 10A is a diagram schematically illustrating a relationship between the light transmission region 32a and a position of an exposure pattern in a case where a conventional mask 32′ (where the position where the exposure pattern is to be formed and the position of the light transmission region are substantially along the optical axis direction), and FIG. 10B is a diagram schematically illustrating a relationship between the light transmission region 32a and the position of the exposure pattern in a case where a mask 32 in which the conventional mask 32′ has been enlarged A times is used.

FIG. 11 is a diagram illustrating the illumination and uniformity when the distance between a lamp 211a and a reflecting mirror 211b is changed.

FIG. 12 is a diagram illustrating a relationship between a declination angle and the position of the workpiece W.

FIG. 13 is a graph showing the relationship between the position in the y direction and the amount of shift of the workpiece W when considering the declination angle.

FIG. 14 is a diagram schematically illustrating a relationship between a workpiece W and a mask 32A when the mask 32A is used.

FIG. 15 is a diagram illustrating an ideal path of light when parallel light is incident on a fly-eye lens 112.

FIG. 16 is a diagram illustrating an actual path of light when parallel light is incident on the fly-eye lens 112.

FIG. 17 is a diagram illustrating positional shifts in the exposure pattern when light inclined with respect to an optical axis is irradiated.

### DESCRIPTION OF EMBODIMENTS

Below, detailed description of embodiments of the present invention will be given with reference to drawings. An example of a polarized light irradiation device is described below in which n alignment film of a liquid crystal panel and the like is generated by photoalignment processing executed with light emitted from a light source passing through a fly-eye lens that uniformizes the intensity distribution of the light, a collimating unit (e.g., collimator) that collimates the light passed through the fly-eye lens to parallel light, a polarizer, and the like so that polarized light is emitted onto an exposed surface of a workpiece W (a glass substrate with a surface provided with an orientation material film). The photoalignment process is a process to give anisotropy to a film by radiating linearly polarized ultraviolet light onto a polymeric film to induce a rearrangement or an anisotropic chemical reaction of molecules within the film.

### Characteristics of Optical System

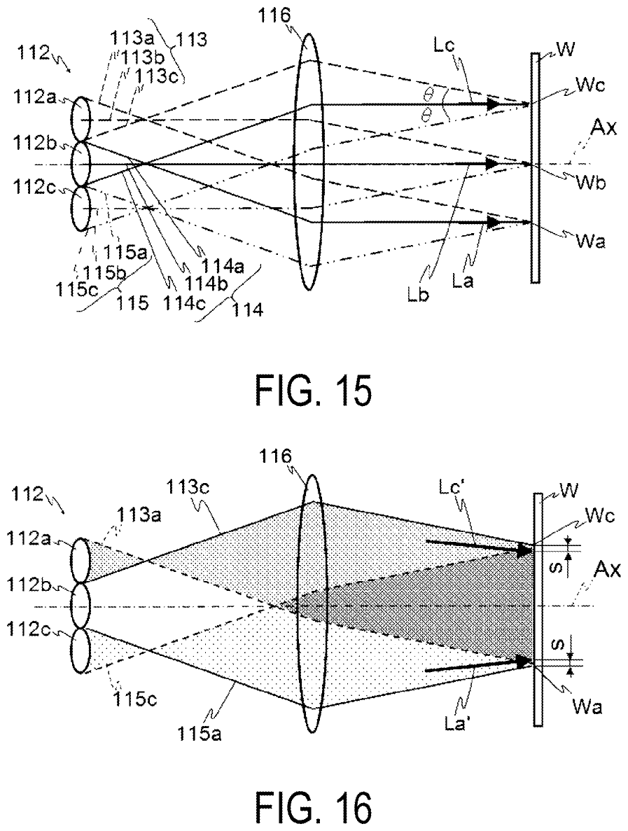

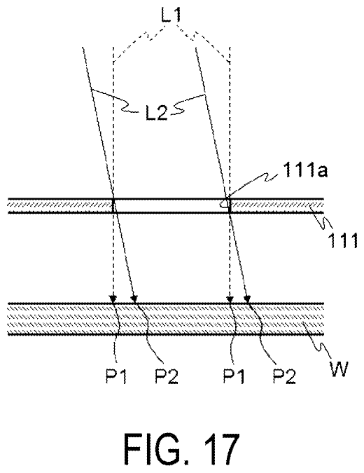

First of all, characteristics of an optical system in a polarized light irradiation device will be described. FIG. 15 is a diagram illustrating an ideal optical path in a case that parallel light is made incident on a fly-eye lens 112. For the sake of description, the fly-eye lens 112 is assumed to include three lenses 112a, 112b, and 112c. The fly-eye lens 112 and a condenser lens 116 are arranged to have the same F-number, that is, are arranged with the posterior focal position of the fly-eye 112 and the anterior focus position of the condenser lens 116 matching.

Incident light is incident on each of the lenses 112a, 112b, and 112c. Light 113 that passed through the lens 112a, light 114 that passed through the lens 112b, and light 115 that passed through the lens 112c are focused for each of the lenses 112a, 112b, and 112c to be emitted on to a workpiece W via the condenser lens 116.

Light 113a passing through the upper end of the lens 112a, light 114a passing through the upper end of the lens 112b, and light 115a passing through the upper end of the lens 112c are each incident on a lower end point Wa of an exposure area of the workpiece W. Light 113b passing through the center of the lens 112a, light 114b passing through the center of the lens 112b, and light 115b passing through the center of the lens 112c are each incident on a center point Wb of the exposure area of the workpiece W. Light 113c passing through the lower end of the lens 112a, light 114c passing through the lower end of the lens 112b, and light 115c passing through the lower end of the lens 112c are each incident on an upper end point Wc of the exposure area of the workpiece W.

Since the center of the lens 112b substantially matches the optical axis Ax, the light 114 emitted from the lens 112b is incident on the points Wa, Wb, and Wc while being parallel to the optical axis Ax. An angle θ between the light 113 and the light 114, and an angle θ between the light 114 and the light 115 are a collimation half-angle.

In FIG. 15, light La, Lb, Lc indicates the center of gravity position and orientation of the light incident on the point Wa, Wb, Wc. In the ideal optical path illustrated in FIG. 15, the intensities of the light 113, the light 114, and the light 115 are substantially the same. Thus, the light La, the light Lb, and the light Lc are substantially parallel to the optical axis Ax, as in the case of the light 114.

In practice, however, the light incident on the lens 112a, 112b, and 112c involves non-uniform light intensity distribution where the intensity of the incident light is low near an end (near the upper end of the lens 112a and the lower end of the lens 112c), and is higher at a position closer to the optical axis Ax. FIG. 16 is a diagram illustrating an actual optical path in a case that light involving a non-uniform light intensity distribution is incident on the fly-eye lens 112. In FIG. 16, a solid line indicates strong light and a dashed line indicates weak light.

In FIG. 16, light La′, Lc′ indicates the center of gravity position of light incident on the point Wa, Wc and the orientation of the light. The light incident on the point Wa includes the light 113a that is weak and the light 115a that is strong. The light incident on the point Wc includes the light 113c that is strong and the light 115c that is weak. Thus, light is emitted onto each of the points Wa and Wc, with weaker light on the outward side and stronger light on the inward side. As a result, light La′, Lc′ is inclined relative to the apparent optical axis Ax.

By tilting the light La′, Lc′ relative to the optical axis Ax, the position of the exposure pattern exposed by the light La′, Lc′ moves by a shift amount S to be closer to the optical axis Ax side than the point Wa, Wc. The present invention shifts the position of the exposure pattern by the shift amount and makes the position of the exposure pattern of the workpiece W that is exposed substantially match the originally intended position.

### First Embodiment

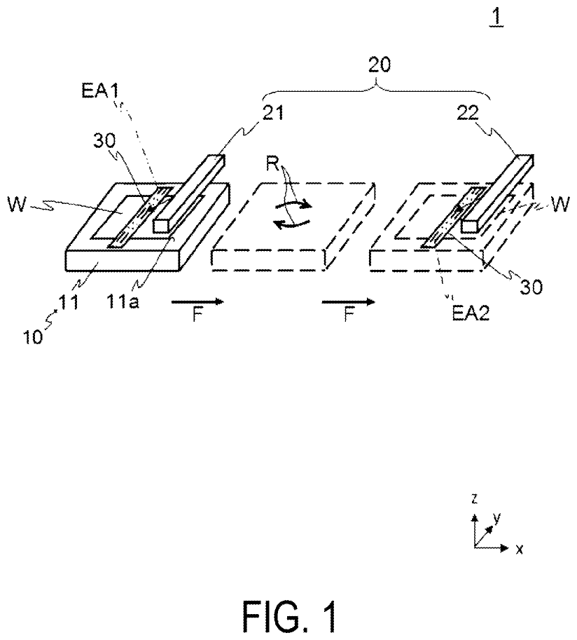

FIG. 1 is a schematic perspective view of a polarized light irradiation device 1 according to a first embodiment. Hereinafter, a transport direction (i.e., the scanning direction) F of the workpiece W is referred to as the x direction, a direction orthogonal to the transport direction F is referred to as the y direction, and the vertical direction is referred to as the z direction.

The polarized light irradiation device 1 mainly includes a transport unit 10 configured to transport the workpiece W, a light irradiation unit 20 configured to emit exposure light, and a mask unit 30.

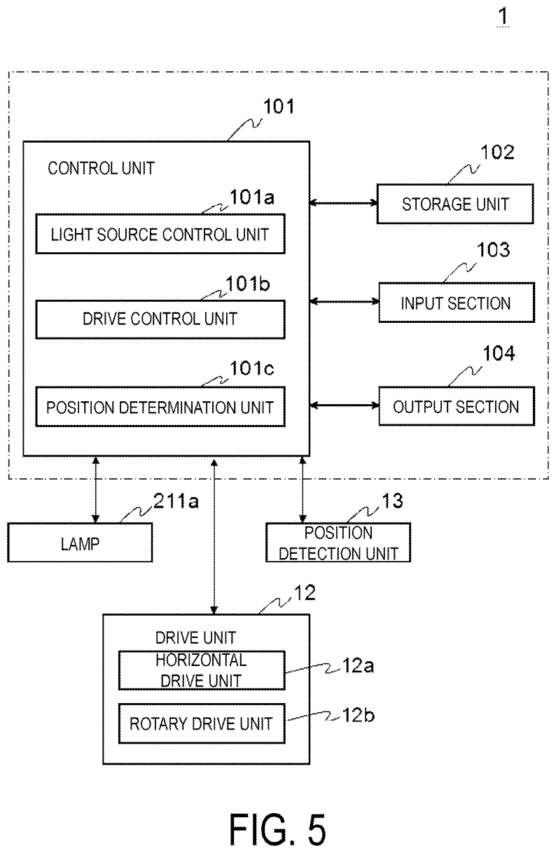

The transport unit 10 mainly includes a stage 11 having a top surface 11a on which the workpiece W is placed, a drive unit 12 configured to drive the stage 11 (see FIG. 5), and a position detection unit 13 configured to measure the position of the stage 11 (see FIG. 5).

The drive unit 12 includes a horizontal drive unit 12a configured to move the stage 11 in the horizontal direction (see FIG. 5), and a rotary drive unit 12b configured to rotate the stage 11 (see FIG. 5). The horizontal drive unit 12a includes an actuator (not illustrated) and a drive mechanism, and is configured to move the stage 11 along the transport direction F. The rotary drive unit 12b includes an actuator (not illustrated) and a drive mechanism (not illustrated), and is configured to rotate the stage 11 by approximately 180°. The stage 11 is rotated by approximately 180° between a light irradiation unit 21 (described in detail later) and a light irradiation unit 22 (described in detail later) by the rotary drive unit 12b.

The position detection unit 13 is, for example, a sensor or a camera. When the stage 11 moves in the transport direction F, the position of the stage 11 is detected by the position detection unit 13.

The light irradiation unit 20 radiates light onto the workpiece W. The light irradiation unit 20 mainly includes two light irradiation units 21 and 22 provided along the x direction.

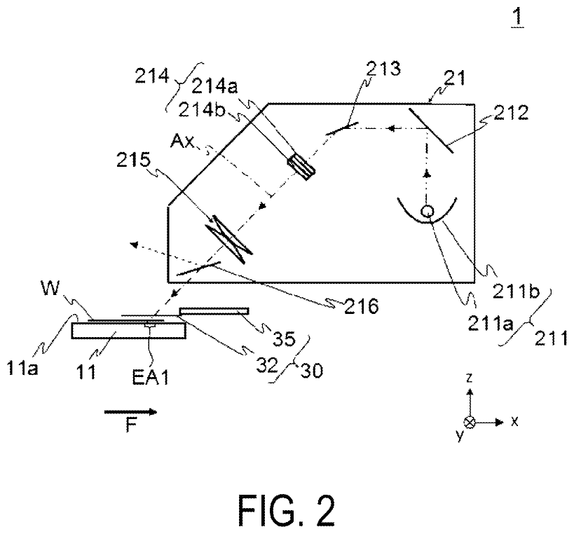

FIG. 2 is a schematic front view illustrating the polarized light irradiation device 1 with a portion thereof enlarged. FIG. 2 provides a see-through image of a main part of the light irradiation unit 21. Since the light irradiation unit 21 and the light irradiating unit 22 have an identical configuration, description of the light irradiation unit 22 will be omitted.

The light irradiation unit 21 mainly includes a light source 211, mirrors 212 and 213, a fly-eye lens 214, a condenser lens 215, and a polarizing beam splitter (PBS) 216. The light irradiation unit 21 is configured to radiate the polarized light onto the workpiece W in a diagonal direction (a direction inclined (by approximately 50° to approximately 70° for example) relative to the z direction) relative to the top surface 11a of the stage 11.

The light source 211 mainly includes a lamp 211a and a reflective mirror 211b provided on a back side of the lamp 211a. The lamp 211a is, for example, a mercury lamp, and is configured to emit unpolarized light (e.g., ultraviolet light). Note that a xenon lamp, an excimer lamp, an ultraviolet LED, or the like may also be used as the lamp 211a. The reflective mirror 211b is, for example, an elliptical reflective mirror, and is configured to reflect light of the lamp 211a forward.

The light emitted from the lamp 211a is reflected by the reflective mirror 211b and is redirected by the mirrors 212 and 213. Consequently, the resultant light is led to the fly-eye lens 214. The two-dot chain lines in FIG. 2 indicate the paths of the light, and the arrows indicate the traveling directions of the light. The light emitted from the lamp 211a and guided to the fly-eye lens 214 is a band of light with an intensity being higher at a center portion, including the optical axis, than at the peripheral edge (detailed later). Note that only the position of the optical axis Ax is illustrated in FIG. 2.

The fly-eye lens 214 has a light incident side lens array 214a and a light emitting side lens array 214b provided opposite to each other. The light incident side lens array 214a and the light emitting side lens array 214b each have a plurality of small lenses (unit lenses).

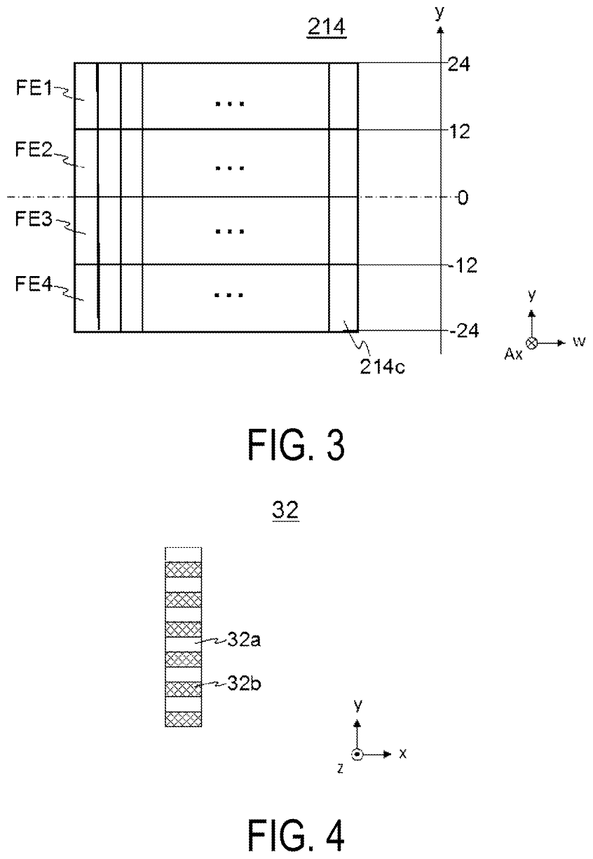

FIG. 3 is a schematic view of the fly-eye 214 as viewed from a direction substantially orthogonal to the optical axis Ax. In FIG. 3, it is assumed that a +y direction is the upward direction, and a w direction is a direction substantially orthogonal to the y direction. The numerical value shown on the right side of FIG. 3 indicates the position of the fly-eye 214 in they direction, with 0 indicating the position overlapping with the optical axis Ax. A yw plane is a plane substantially orthogonal to the optical axis Ax.

The unit lens 214c has a substantially rectangular shape, and the longitudinal direction is substantially parallel to the y direction. Unit lenses 214c are arranged in a matrix along the yw plane. The number of unit lenses 214c arranged in the y direction is four, and the number of unit lenses 214c arranged in the w direction is five or more (e.g., 10).

Hereinafter, the unit lenses 214c at a certain position in the w direction (here, the most −w side) are referred to as lenses FE1, FE2, FE3, and FE4 in order from the +y side.

In FIG. 3, only the unit lenses 214c of the light incident side lens array 214a are illustrated. The unit lenses of the light emitting side lens array 214b are provided at a position overlapping the unit lenses 214c on the farther side relative to the paper plane.

The condenser lens 215 is formed by assembling a plurality of lenses, and is a lens configured to concentrate light. Light passed through the fly-eye lens 214 is concentrated by the condenser lens 215 and is led to PBS 216.

PBS 216 is an optical element configured to split incident light into S-polarized light and P-polarized light by reflecting the S-polarized light (see dotted-line arrow in FIG. 2) and transmitting the P-polarized light.

The mask unit 30 is provided on an optical path of the polarized light emitted from the light irradiation units 21 and 22 to the workpiece W. When the polarized light is emitted from the light irradiation units 21 and 22 to the workpiece W, the mask unit 30 and the top surface 11a are arranged adjacent to each other.

The mask unit 30 mainly includes a mask 32 and a mask holding unit 35. The mask 32 is a substantially plate-like member, and has a substantially rectangular shape in plan view. The mask 32 is held substantially parallel to the top surface 11a by the mask holding unit 35. In addition, the mask 32 is driven in the x direction, the y direction, the z direction, and the θ direction by the mask holding unit 35.

FIG. 4 is a schematic view of the mask 32 as viewed in plan view. The mask 32 includes band-like (band-shaped) light transmission regions 32a each of which extends in the x direction. In addition, the mask 32 band-shaped light blocking regions 32b each of which extends in the x direction. The light transmission regions 32a and the light blocking regions 32b alternate in a direction (specifically, in the y direction) that is substantially orthogonal to the x direction. The P-polarized light that passed through the PBS 216 passes through the light transmission region 32a, to be emitted onto the workpiece W.

FIG. 5 is a block diagram illustrating an electrical configuration of the polarized light irradiation device 1. The polarized light irradiation device 1 mainly includes a control unit 101, a storage unit 102, an input section 103, and an output section 104.

The control unit 101 is a program control device such as a Central Processing Unit (CPU), which is an arithmetic unit. The control unit 101 is configured to operate in accordance with a program stored in the storage unit 102. In the present embodiment, the control unit 101 is configured to function as: a light source control unit 101a configured to control the turning on and off of the lamp 211a; a drive control unit 101b configured to control the drive unit 12 to move or rotate the stage 11; a position determination unit 101c configured to acquire measurement results from the position detection unit 13 and thus to determine the position of the stage 11 and the position of the workpiece W placed on the stage 11; and the like. Note that the techniques for moving and positioning the stage 11 are already publicly known techniques, and thus descriptions thereof will be omitted.

The storage unit 102 is a volatile memory, a non-volatile memory, or the like. The storage unit 102 holds, among other things, programs to be executed by the control unit 101, and operates as a working memory for the control unit 101.

The input section 103 includes an input device such as a keyboard or a mouse. The output section 104 is a display or the like.

Next, the operations of the polarized light irradiation device 1 configured as described above will be described with reference to FIG. 1. The drive control unit 101b makes the horizontal drive unit 12a move the stage 11 along the transport direction F (in the +x direction).

When the position determination unit 101c determines that the workpiece W is about to enter a region to be irradiated with the P-polarized light from the light irradiation unit 21 (i.e., light-irradiated region EA1), the light source control unit 101a turns on the lamp 211a of the light irradiation unit 21. Then, with the lamps 211a kept in that state, the drive control unit 101b moves the stage 11 in the transport direction F. As a result, the workpiece W is continuously irradiated with the light emitted by the light irradiation unit 21. In this process, the polarized light in a band-like form (a band-shape) is emitted on the workpiece W.

When the position determination unit 101c determines that the workpiece W has traveled past the light-irradiated region EA1, the light source control unit 101a turns off the lamp 211a of the light irradiation unit 21. Then, with the lamps 211a kept in that state, the drive control unit 101b moves the stage 11 in the transport direction F.

When the position determining unit 101c determines that the current position of the stage 11 is between the light irradiation unit 21 and the light irradiation unit 22, the drive control unit 101b makes the rotary drive unit 12b rotate the stage 11 by approximately 180° (see arrows R in FIG. 1).

After the stage 11 has been rotated, the drive control unit 101b moves the stage 11 in the transport direction F. When the position determination unit 101c determines that the workpiece W is about to enter a region to be irradiated with the P-polarized light from the light irradiation unit 22 (i.e., light-irradiated region EA2), the light source control unit 101a turns on the lamp 211a of the light irradiation unit 22. Then, with the lamps 211a kept in that state, the drive control unit 101b moves the stage 11 in the transport direction F. As a result, the workpiece W is continuously irradiated with the light emitted by the light irradiation unit 22. The region irradiated with light in this process is a region not irradiated with the light from the light irradiation unit 21.

When the position determination unit 101c determines that the workpiece W has traveled past the light-irradiated region EA2, the light source control unit 101a turns off the lamp 211a of the light irradiation unit 21. Thereafter, the control unit 101 terminates the series of processes.

The polarization light irradiation device 1 is characterized in that the workpiece W is irradiated with light in the light irradiation regions EA1 and EA2, with the position of the exposure pattern shifted by the shift amount so as to substantially match the originally intended position. This will be described in detail below.

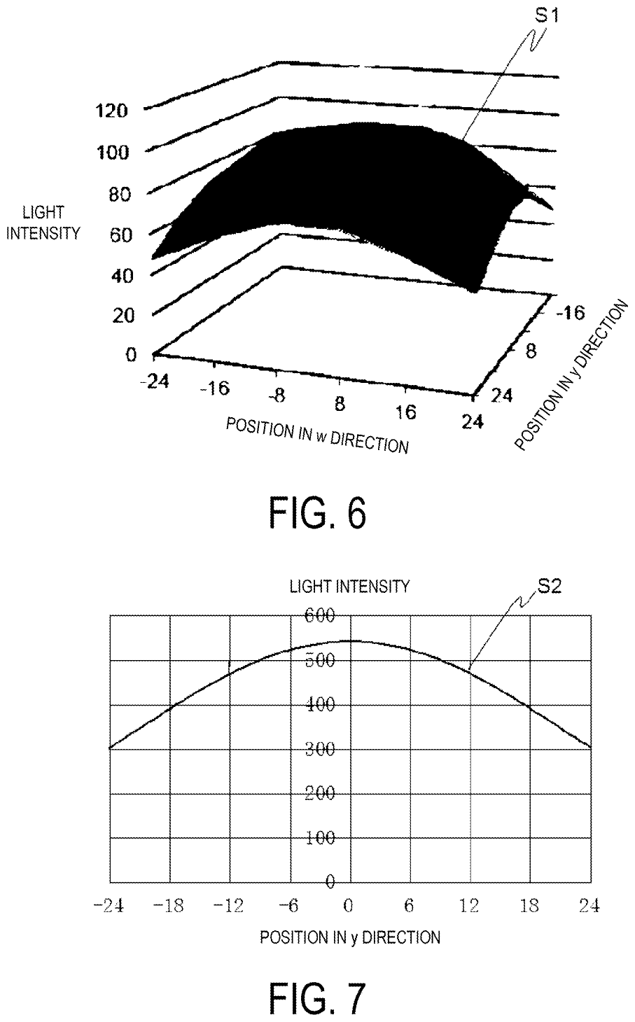

FIG. 6 is a graph illustrating an intensity S1 of light incident on the fly-eye lens 214, and illustrates the relationship between the position on the yw plane of the fly-eyewear lens 214 and the intensity of the light. In FIG. 6, the vertical direction indicates the intensity of the light, and the lower rectangular shape schematically illustrates the position on the fly-eye lens 214. The numerical value on the lower side indicates the position in the w direction about the optical axis Ax, and the numerical value on the right side indicates the position in the y direction about the optical axis Ax.

Light is incident on the entire surface of the fly-eye lens 214. The light guided to the fly-eye lens 214 has a greater intensity at the center than at the peripheral edge.

FIG. 7 illustrates a result (light intensity S2) of adding the amount of light along the line extending in the direction w to the light intensity S1 illustrated in FIG. 6 for each y-direction position of the fly-eye lens 214. In FIG. 7, the horizontal axis indicates the position of the fly-eye lens 214 in the y direction (corresponding to the value on the right side of FIG. 3), and the vertical axis indicates the result of adding the amount of light (light intensity).

The light intensity S2 illustrated in FIG. 7 indicates the relationship between the total amount of light incident on the lenses FE1, FE2, FE3, and FE4 (see FIG. 3) and the position in the y direction, while the workpiece W moving in the transport direction F in the polarized light irradiation device 1 passes through the light irradiation regions EA1 and EA2.

The incident light incident on the lenses FE1, FE2, FE3, and FE4 has a low intensity near both ends in the y direction, and has a higher intensity at a position closer to the optical axis Ax (y=0). Therefore, at positions other than the position on the optical axis Ax, the light incident on the workpiece W includes weak outward light and strong inward light (see FIG. 15). As a result, the center of gravity orientation of the light incident on each position of the workpiece W is inclined relative to the optical axis Ax, and thus the exposure position is shifted by the shift amount (see FIG. 15).

Table 1 is a diagram illustrating the relationship between the position on the fly-eye lens 214 and the light intensity, the position of the workpiece W in the y direction, and the shift amount.

TABLE 1

| Light exposure amount distribution | | | | | | | | | | |
|---|---|---|---|---|---|---|---|---|---|---|
| | FE1 | | FE2 | | FE3 | | FE4 | | | |
| | | Irradiated | | Irradiated | | Irradiated | | Irradiated | | |
| | Amount | position | Amount | position | Amount | position | Amount | position | Position of | Shift |
| Position | of light | offset | of light | offset | of light | offset | of light | offset | workpiece W | amount |
| 1 | 304 | −7.5 | 470 | −2.5 | 543 | 2.5 | 470 | 7.5 | −125 | 0.80 |
| 2 | 318 | | 481 | | 542 | | 458 | | −104 | 0.67 |
| 3 | 333 | | 492 | | 541 | | 446 | | −83 | 0.54 |
| 4 | 348 | | 501 | | 538 | | 433 | | −63 | 0.40 |
| 5 | 362 | | 510 | | 534 | | 419 | | −42 | 0.27 |
| 6 | 377 | | 517 | | 530 | | 406 | | −21 | 0.13 |
| 7 | 392 | | 524 | | 524 | | 391 | | 0 | 0.00 |
| 8 | 406 | | 530 | | 517 | | 377 | | 21 | −0.14 |
| 9 | 420 | | 534 | | 509 | | 362 | | 42 | −0.27 |
| 10 | 433 | | 538 | | 501 | | 347 | | 63 | −0.41 |
| 11 | 446 | | 541 | | 491 | | 333 | | 83 | −0.54 |
| 12 | 459 | | 542 | | 481 | | 318 | | 104 | −0.67 |
| 13 | 470 | | 543 | | 470 | | 304 | | 125 | −0.80 |

Table 1 is described. The “Position” indicates the position in the lenses FE1, FE2, FE3, and FE4 (see FIG. 3) in the y direction, where 1 corresponds to the +y side and 13 corresponds to the −y side. The “Amount of light” indicates the total amount of incident light at positions 1 to 13 of the lenses FE1, FE2, FE3, and FE4. The “irradiation position offset” indicates a shift of the exposure position in the y direction due to the collimation half-angle (see FIG. 15), with the gap between the workpiece W and the mask 32 being 200 μm.

The “Position of workpiece W” indicates the incident positions (positions in the y direction), on the workpiece W, of the light at the positions 1 to 13 on the lens FE1, FE2, FE3, and FE4. The “Shift amount” indicates the shift amount per position of the workpiece W, which is determined by Equation (1).

[Equation 1]

Shift amount=(FE1 amount of light×FE1 irradiation position offset+FE2 amount of light×FE2 irradiation position offset+FE3 amount of light×FE3 irradiation position offset+FE4 amount of light×FE4 irradiation position offset)/(FE1 amount of light+FE2 amount of light+FE3 amount of light+FE4 amount of light) (1)

The shift amount at a certain position on the workpiece W (referred to as position p) is calculated by calculating the product of the amount of light and the shift amount at the position P for each of FE1, FE2, FE3, and FE4, and dividing the sum of these by the sum of the amounts of light at the position p on the FE1, FE2, FE3, and FE4. The shift amount is 0 on the optical axis Az (in a case that the position of the workpiece W=0 in Table 1) and increases toward the end of the workpiece W (as the absolute value of the value indicating the position of the workpiece W increases in Table 1).

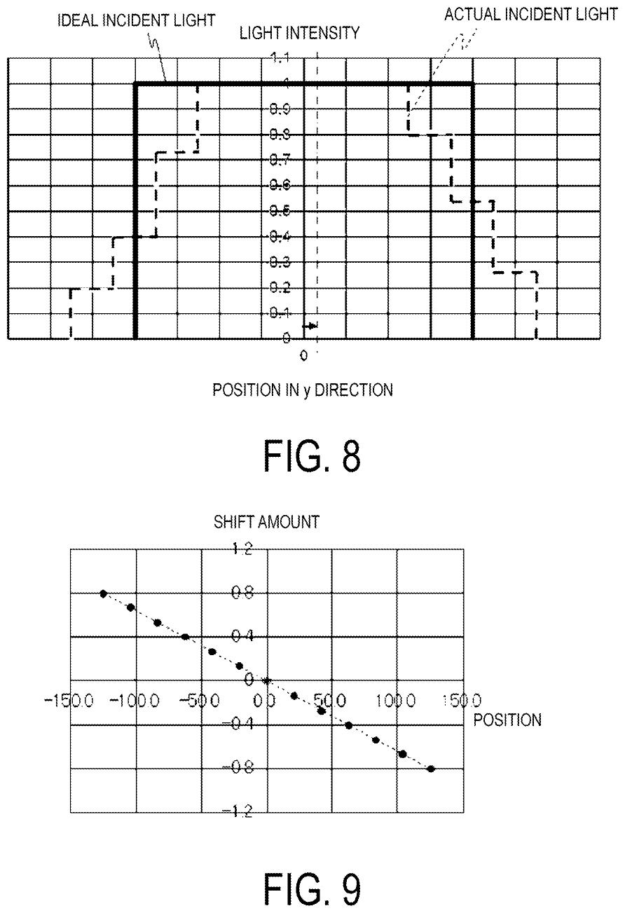

FIG. 8 is a diagram illustrating a comparison between the ideal incident light and the actual incident light, passing through the light transmission region 32a, in a case that the position of the workpiece W in Table 1 is 125. The horizontal axis in FIG. 8 indicates a position in the y direction, with a value 0 indicating the case where the position of the workpiece W is 125, a value more on the right side indicating a position closer to the optical axis Ax, and a value more on the left side indicating a position farther from the optical axis Ax. The vertical axis in FIG. 8 indicates the intensity of light as a relative value with the intensity of light at the portion with the highest light intensity being 1.

The center of gravity of the actual incident light illustrated by the dotted line in FIG. 8 (see the dot-dash line in FIG. 8) is shifted by a shift amount toward the optical axis Ax (see arrow in FIG. 8), from the center of gravity of the ideal incident light indicated by the solid line in FIG. 8 (y=0 in FIG. 8).

Note that the ideal incident light position indicated by the solid line in FIG. 8 is the same as the position of the light transmission region 32a of the mask 32.

In the present embodiment, the position of the light transmission region 32a provided in the mask 32 is adjusted so as to shift the position of the exposure pattern by the amount of shift. Specifically, in order to make the center of gravity of actual incident light match the center of gravity of ideal incident light, the position of the light transmission region 32a is translated away from the optical axis Ax by an absolute value of the shift amount. For example, in FIG. 8, when the light transmission region 32a is moved in the −y direction by the shift amount, the position of the center of gravity of the actual incident light (refer to the dot-dash line in FIG. 8) is moved in the −y direction by the shift amount and overlaps with y=0.

As a result, the position of the exposure pattern on the workpiece W that is exposed, is shifted by the shift amount, to substantially match the originally intended position.

FIG. 9 is a graph illustrating the relationship between the position in the y direction and the shift amount of the workpiece W. The horizontal axis indicates the “Position of the workpiece W” in Table 1, and the vertical axis indicates the “shift amount” in Table 1.

As illustrated in FIG. 9, the position in the y direction and the shift amount of the workpiece W are proportional to each other. Translation of the light transmission region 32a away from the optical axis Ax by the absolute value of the shift amount results in a distance, between the light transmission region 32a and the optical axis Ax, being A (A is a number equal to or greater than 1) times as long as the distance between the position of the exposure pattern formed by the light passed through the light transmission region 32a and the optical axis Ax. Thus, the size of the mask 32 is A times as large as the size of the exposed region of the workpiece W. In a case illustrated in FIG. 9 (a case where a gap between the workpiece W and the mask 32 is 200 μm), the slope of the graph is −0.0064, and thus A is 1.0064 (1+0.0064).

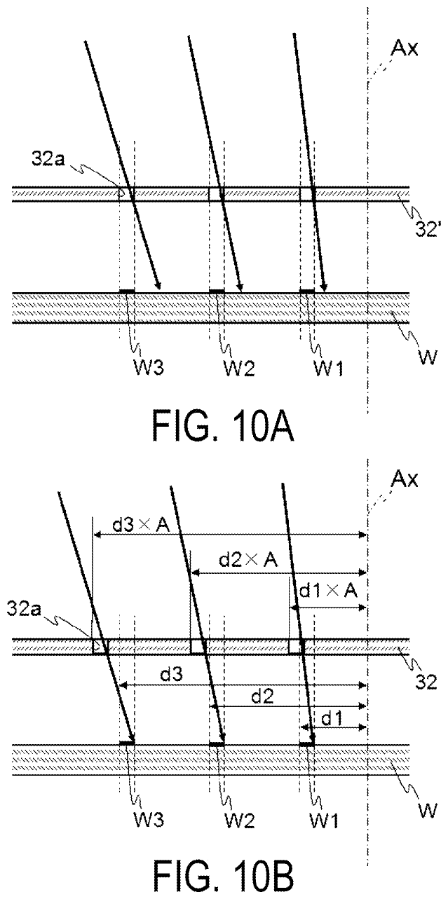

FIG. 10A is a diagram schematically illustrating a positional relationship between the light transmission region 43a and the exposure pattern in a case that a conventional mask 32′ is used (exposure patterns W1, W2, and W3 that are supposed to be formed and the light transmission region 32a are arranged substantially along the optical axis direction). FIG. 10B is a diagram schematically illustrating a positional relationship between the light transmission region 43a and the exposure pattern in a case that the mask 32 as a result of enlarging the conventional mask 32′ by a factor of A is used. In FIG. 10, incident light is indicated by arrows. In FIGS. 10A and 10B, the left and right direction on the paper plane corresponds to the y direction.

In the case illustrated in FIG. 10A, the position of the exposure pattern where the workpiece W is exposed is shifted by the shift amount because the position of the light transmission region 32a substantially match the positions of the exposure patterns W1, W2, and W3 that are supposed to be formed.

In contrast, in FIG. 10B, the position of the light transmission region 32a is outside of the originally intended position of the light exposure pattern W1, W2, W3 (has a larger distance from the optical axis Ax), and the distance between the light transmission region 32a and the optical axis Ax is A times as long as the distance d1, d2, d3 between the exposure pattern W1, W2, W3 and the optical axis Ax. Thus, the exposure patterns W1, W2, and W3 are formed at the originally intended position.

According to the present embodiment, the distance between the light transmission region 32a and the optical axis Ax is set to be A times as long as the distance between the exposure pattern formed by the light passed through the light transmission region 32a and the optical axis Ax, so that the position of the exposure pattern that is actually exposed can match the originally intended position of the exposure pattern. In particular, the present embodiment is effective when the number unit lenses arranged in the direction substantially orthogonal to the transport direction of the unit lens (in they direction) is small (here, four).

Furthermore, according to the present embodiment, the position of the light transmission region 32a is adjusted so that the position of the exposure pattern actually exposed can match the originally intended position of the exposure pattern, and thus only a single set of fly-eyewear lens and condenser lens is required, whereby the device can be prevented from having a large size and can be manufactured at a lower cost.

Note that in the present embodiment, the size of the mask 32 is A times as large as the size of the exposure region of the workpiece W, and A is a value depending on the distance between the mask 32 and the workpiece W instead of being a fixed value. Specifically, A increases as the distance between the mask 32 and the workpiece W (hereinafter, referred to as the gap) increases, and decreases when the gap decreases. Still, A will never be equal to or less than 1.

In addition, even if the mask 32 used is the same, the shift amount changes when the gap changes. Thus, the mask 32 that is larger than the size of the exposure region of the workpiece W may be used and the mask 32 may be moved by the z direction by the mask holder 35, so that the position of the exposure pattern is shifted by the shift amount. As a result, even in a case that the gap varies, the position of the exposure pattern can be shifted by the shift amount with the same mask 32.

In the present embodiment, the position of the exposure pattern is shifted by the shift amount using the mask 32 with which the distance between the light transmission region 32a and the optical axis Ax is A times as long as the distance between the light exposure pattern formed by light passing through the light transmission region 32a and the optical axis Ax. Alternatively, a method of shifting the position of the exposure pattern with the intensity distribution of light incident on the fly-eye lens 214 approximated to a uniform distribution can be contemplated.

In this case, a lamp movement unit (not illustrated) that moves the lamp 211a along the optical axis Ax is provided. The lamp movement unit has a known movement mechanism and an actuator.

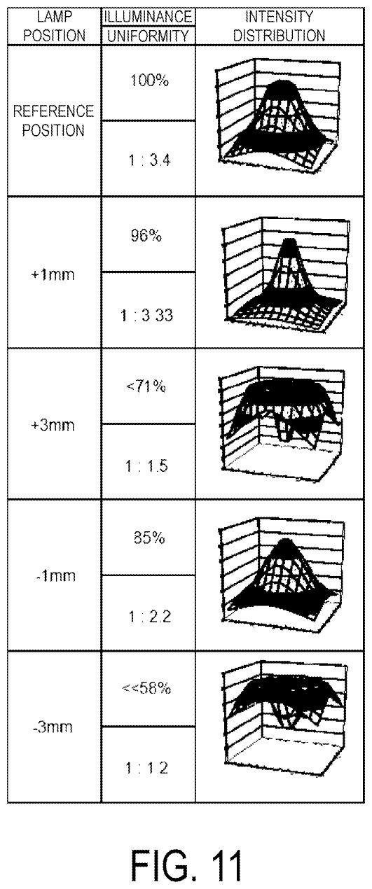

FIG. 11 is a diagram illustrating the illumination and uniformity in a case that the distance between the lamp 211a and the reflective mirror 211b is varied. In FIG. 11, the lamp position is defined by the distance between the lamp 211a and the reflective mirror 211b, and the illumination is a total amount of light incident on the fly-eye lens 214 with the total amount of light incident on the fly-eye lens 214 in the state where the lamp position is at a reference position defined as 100%, and the uniformity is the ratio between the strongest light and the weakest light in the light incident on the fly-eye lens 214. Furthermore, in FIG. 11, the intensity distribution is a graph indicating the intensity distribution of light emitted from the reflective mirror 211b, wherein a region of the central portion of the graph corresponds to the incidence on the fly-eye lens 214.

The reference position corresponds to the distance between the lamp 211a and the reflecting mirror 211b at the positions illustrated in FIG. 2. The graph in FIG. 6 is a result of enlarging the central portion of the graph of intensity distribution at the reference position in FIG. 11.

Cases where the lamp position is +1 mm, +3 mm, −1 mm, and −3 mm respectively corresponds to a case that the distance between the lamp 211a and the reflective mirror 211b is increased by 1 mm, a case that the distance between the lamp 211a and the reflective mirror 211b is increased by 3 mm, a case that the distance between the lamp 211a and the reflective mirror 211b is reduced by 1 mm, and a case that the distance between the lamp 211a and the reflective mirror 211b is reduced by 3 mm. By setting the lamp position to +3 mm or −3 mm, the intensity distribution of light incident on the fly-eye lens 214 is approximated to the uniform distribution.

However, in the cases where the lamp position is +3 mm and −3 mm, no more than 71% and no more than 58% light can be used respectively, compared with the case where the lamp position is at the reference position. Considering this, it is more preferable to adjust the position of the light transmission region 32a than to move the lamp 211a, for shifting the exposure pattern is shifted by the shift amount. Still, the lamp 211a may be moved in the optical axial direction while using a mask with which the distance between the light transmission region 32a and the optical axis Ax is greater than the distance between the light exposure pattern formed by the light passing through the light transmission region 32a and the optical axis Ax. The two methods can be used in combination to efficiently shift the position of the exposure pattern.

### Second Embodiment

In the first embodiment, the distance between the light transmission region 32a and the optical axis Ax is A times as long as the distance between the exposure pattern formed by light passing through the light transmission region 32a and the optical axis Ax. However, the arrangement of the light transmission region 32a is not limited to this.

In a second embodiment, a mask that takes into account a declination angle is used. Now, a polarized light irradiation device according to the second embodiment will be described. Note that the embodiment is the same as the polarized light irradiation device 1 according to the first embodiment except for the mask. Thus, only a mask 32A used in the polarized light irradiation device according to the second embodiment will be described below.

First of all, the declination angle will be described. The declination angle is an angle between the optical axis and light passing through the peripheral portion of the condenser lens 215, in a case where this light is inclined relative to the optical axis due to the spherical aberration of the condenser lens 215. The declination angle is not limited to an angle that becomes the greatest at the outermost edge of the irradiated region, and the magnitude and an occurrence situation thereof depend on the properties of the lens.

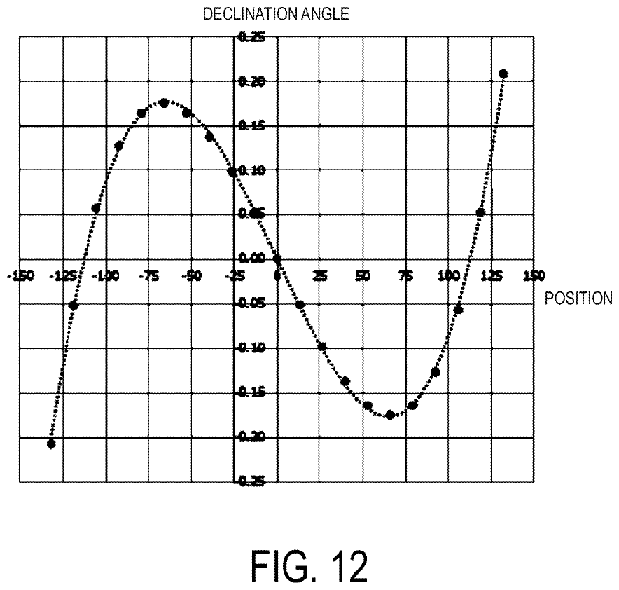

FIG. 12 is a diagram illustrating the relationship between the declination angle and the position of the workpiece W. In FIG. 12, the horizontal axis indicates the position of the workpiece W in they direction, and the vertical axis indicates the declination angle. In FIG. 3, the declination angle is small at the center portion of the irradiated region and is large at the peripheral edge portion. The declination angle is the largest at a region slightly inward from the outermost edge portion.

Note that the declination angle depends on the lens, meaning that the declination angle illustrated in FIG. 12 is merely an example, and that the graph in FIG. 12 varies among different shapes and the like of the condenser lens 215.

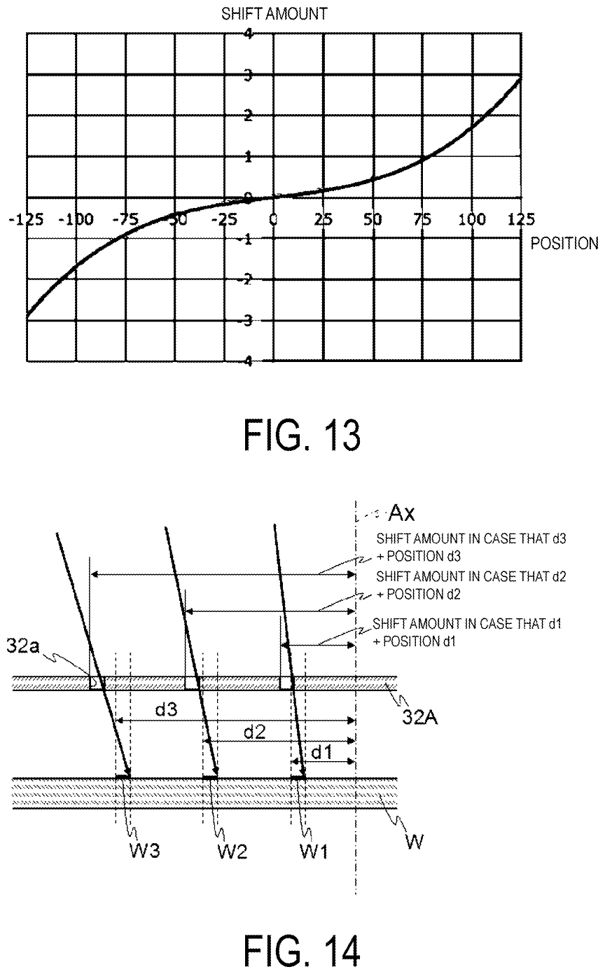

FIG. 13 is a graph illustrating the relationship between the position of the workpiece W in the y direction and the shift amount, while taking account of the declination angle. The graph in FIG. 13 is obtained by adding the shift amount due to the declination angle in FIG. 12 to the graph in FIG. 9.

FIG. 14 is a diagram schematically illustrating the relationship between the light transmission region 32a and the position of the exposure pattern in the case that the mask 32A is used. As illustrated in FIG. 14, the distance between the light transmission region 32a and the optical axis Ax in the case that the mask 32A is obtained by adding, to the distance between the exposure pattern that is originally intended to be formed by the light passing through the light transmission region 32a and the optical axis Ax, the shift amount corresponding to the position of the exposure pattern illustrated in FIG. 13.

With the present embodiment, even in a case where the effect of the exposure angle is too large to be ignored, the position of the exposure pattern actually exposed can match the originally intended position of the exposure pattern.

Embodiments of the invention have been described in detail with reference to the drawings. However, specific configurations are not limited to the embodiments, and changes in the design or the like are also included within a scope which does not depart from the gist of the invention.

The present invention is not limited to polarizing light irradiation devices, and can be applied to various types of light irradiation devices. For example, a polarization element is not an essential element, and a device for irradiating the workpiece W with unpolarized light is also included in the present invention. Furthermore, although the two light irradiation units 21 and 22 are provided in the present embodiment, only a single light irradiation unit may be provided.

Further, the term “substantially” in the present invention is not to be understood as merely being strictly the same, and is a concept that includes variations and modifications to an extent that does not result in loss in identity. For example, a term “substantially parallel” and a term “substantially orthogonal” are not limited to “strictly parallel” and “strictly orthogonal”. In addition, for example, terms such as “parallel”, “orthogonal”, and the like include “substantially parallel”, “substantially orthogonal”, and the like, respectively. To put it differently, those terms are not strictly limited to the parallel state, orthogonal state, and the like, respectively. In addition, the term “proximity” is used in the present invention to mean a concept where, for example, a place in the proximity of a certain point A may include the point A or otherwise as long as the place is near the point A.

### REFERENCE SIGNS LIST

1 Polarized light irradiation device
10 Transport portion
11 Stage
11a Top surface
12 Driving unit
12a Horizontal drive unit
12b Rotary driving unit
13 Position detection unit
20, 21, 22 Light irradiation unit
30, 30A Mask unit
32, 32a, 32′ Mask
32a Light transmission region
32b Light blocking region
35 Mask holding unit
101 Control unit
101a Light source control unit
101b Drive control unit
101c Position determination unit
102 Storage unit
103 Input section
104 Output section
111 Photomask
111a Opening
112 Fly-eye lens
112a, 112b, 112c Lens
113, 113a, 113b, 113c Light
114, 114a, 114b, 114c Light
115, 115a, 115b, 115c Light
116 Condenser lens
211 Light source
211a Lamp
211b Reflective mirror
212, 213 Mirror
214 Fly-eye lens
214a Light incident side lens array
214b Light emitting side lens array
214c Unit lens
215 Condenser lens
216 PBS

1. A light irradiation device that forms an exposure pattern in a band-shape along a first direction of a substrate, the light irradiation device comprising:
a light source that emits light;
a mask that is formed at a position where a light transmission region having a band-shape along the first direction does not intersect with an optical axis;
a collimator that converts the light emitted from the light source into substantially parallel light to be emitted onto the mask; and
a fly-eye lens that is disposed between the light source and the collimator and achieves a uniform distribution of an intensity of the light emitted from the light source, wherein
a distance between the light transmission region and the optical axis in a second direction substantially orthogonal to the first direction is A times as long as a distance between an exposure pattern formed on the substrate by light that passed through the light transmission region and the optical axis, A being a number that is equal to or larger than 1.

2. The light irradiation device according to claim 1, further comprising:
a stage on which the substrate is placed; and
a mask movement unit that moves the mask along a direction substantially orthogonal to a top surface of the stage.

3. The light irradiation device according to claim 1, wherein
the light source includes a lamp that emits light and a reflection mirror that is provided on a back side of the lamp, and
the light irradiation device further comprises a lamp movement unit that moves the lamp along the optical axis.

4. The light irradiation device according to claim 2, wherein
the light source includes a lamp that emits light and a reflection mirror that is provided on a back side of the lamp, and
the light irradiation device further comprises a lamp movement unit that moves the lamp along the optical axis.
